(19) United States
(12) Patent Application Publication
(10) Pub. No.: US 2009/0104374 A1
(43) Pub. Date: Apr. 23, 2009

(54) Substrate Processing Method Using A Substrate Processing Apparatus

(75) Inventor: Akira Kumagai, Tokyo (JP)

Correspondence Address: BUCHANAN, INGERSOLL & ROONEY PC, POST OFFICE BOX 1404, ALEXANDRIA, VA, 22313-1404, US

(73) Assignee: CANON ANELVA CORPORATION, Kanagawa-ken (JP)

(21) Appl. No.: 12/276,353

(22) Filed: Nov. 23, 2008

Related U.S. Application Data
(62) Division of application No. 11/161,293, filed on Jul. 28, 2005.

(30) Foreign Application Priority Data
Aug. 4, 2004 (JP) 2004-227747

(51) Int. Cl. C23C 16/44

(52) U.S. Cl. 427/569

(57) ABSTRACT

A substrate processing apparatus vacuum reactor is internally divided into an upper part and a lower part that are separated from each other by an electrically conductive partitioning plate grounded. The upper part of the vacuum reactor is a plasma discharge space in which an rf electrode is arranged, and the lower part of the vacuum reactor is a substrate process space in which a substrate support mechanism is disposed. The partitioning plate has a plurality of through-holes that are provided to pass vertically through it, and has an internal space that is isolated from the plasma discharge space and communicates with the substrate process space. Each of the plurality of through-holes provided on the partitioning plate has a vertical length of between 5 mm and 30 mm, a bore diameter of between 5 mm and 30 mm and an aspect ratio of above 1 and below 2.

### CROSS-REFERENCE TO RELATED APPLICATIONS

The present application is a division of U.S. Ser. No. 11/161,293, filed on Jul. 28, 2005, and which claims the priority of JP 2004-227747, filed on Aug. 4, 2004. The contents of U.S. Ser. No. 11/161,293 and JP 2004-227747 are incorporated herein by reference.

### BACKGROUND OF THE INVENTION

1. Field of the Invention

The present invention relates to a substrate processing apparatus that includes a vacuum reactor in which plasma is generated and an electrically neutral excited active species (which will be referred hereinafter to as “radicals”) may then be produced from such plasma and in which the processes such as, for example, the process of depositing a thin film on a substrate placed within the vacuum reactor, the process of finishing the surface of the thin film thus deposited and the like may be performed on the substrate using those radicals. Furthermore, the present invention relates to a substrate processing method that may be performed by using the substrate processing apparatus defined above.

2. Related Art

The substrate processing apparatus and substrate processing method wherein and whereby the radicals are produced by generating plasma within the vacuum reactor and the processes such as, for example, the process of depositing a thin film on the substrate placed within the vacuum reactor, the process of finishing the surface of the thin film thus deposited, thereby improving the film quality, and the like are performed using the radicals are currently used in a variety of applications.

For example, a plasma enhanced CVD is currently used as the substrate processing apparatus and in the substrate processing method performed by using the substrate processing apparatus, wherein a Silicon oxide film may be deposited at a low temperature as a gate insulating film in the production of a liquid crystal display (LCD) using a low temperature polysilicon type TFT.

As disclosed in our prior Japanese Patent Application No. Heisei 11-157692 filed on Jun. 4, 1999 and now published under JP Publication No. 2000-345349, a CVD apparatus is proposed as the substrate processing apparatus. In this CVD apparatus of JP Patent Application No. H 11-157692 (JP Patent Publication No. 2000-345349), radicals may be produced by generating plasma within the vacuum reactor and in which the process such as the film deposition process may be performed on a substrate placed within the vacuum reactor.

In this specification, the CVD apparatus disclosed in the above patent application (JP Patent Application No. H 11-157692 now published under JP Patent Publication No. 2000-345349) is referred to as “RS-CVD apparatus” that stands for the Radical-Shower CVD apparatus, in order to distinguish this CVD apparatus from the usual plasma enhanced CVD apparatus.

In the Japanese patent application publication No. 2000-345349, the RS-CVD apparatus is proposed as the apparatus in which radicals may be produced by generating plasma within the vacuum reactor and the film deposition process may be performed on the substrate using the produced radicals and an appropriate film deposition gas.

Specifically, in the RS-CVD apparatus described in the patent application publication No. 2000-345349, it is proposed that the apparatus may be used in the following manner.

Firstly, the vacuum reactor may be internally divided into a plasma discharge space and a film deposition process space (which is functionally equivalent to the substrate process space) that are separated from each other by means of an electrically conductive partitioning plate grounded to the earth. This electrically conductive partitioning plate has a plurality of through-holes, and the plasma discharge space and film deposition process space are provided to communicate with each other only through the through-holes on the partitioning plate. An appropriate gas may be delivered into the plasma discharge space for generating plasma, and radicals may then be produced from such plasma. Then, the radicals may be delivered into the film deposition process space through the through-holes in the partitioning plate. In the film deposition process space, the film deposition gas delivered directly into the film deposition process space and the radicals delivered into the film deposition process space through the through-holes on the partitioning plate are then allowed to react with each other, and the film deposition process is performed on the substrate (for example, a glass substrate having the Size of 370 mm×470 mm) placed in the film deposition process space.

In the specification, it should be understood that “the film deposition gas delivered directly” into the substrate process space refers to any film deposition gas that may be delivered directly into the substrate process space, that is, the film deposition process space from outside the vacuum reactor, without making contact with the plasma or radicals.

FIG. 8 represents the general construction of the conventional partitioning plate employed in the RS-CVD apparatus when it is used for depositing a thin film on the substrate as proposed in the patent application publication No. 2000-345349.

An electrically conductive partitioning plate 14 that is grounded to the earth contains a plurality of film deposition gas diffusion spaces 24 in each of which the film deposition gas may be diffused. Those film deposition gas diffusion spaces 24 communicate with each other, and are isolated from a plasma discharge space 15 located above them as shown in FIG. 8. The film deposition gas diffusion spaces 24 also communicate with the film deposition process space 16 located below them through a plurality of film deposition gas diffusion holes 26 as shown in FIG. 8. The film deposition gas may be delivered into the film deposition gas diffusion spaces 24 through a film deposition gas delivery port 28b connected to a film deposition gas delivery pipe, and may then be diffused through the film deposition gas diffusion spaces 24 so that it can be supplied through the film deposition gas diffusion holes 26 uniformly onto the surface of a substrate placed in the film deposition process space 16.

The partitioning plate 14 further has a plurality of through-holes 25 that pass through the areas of the partitioning plate 14 where the film deposition gas diffusion spaces 24 are not provided, extending from one Side toward the other Side (in the vertical direction in FIG. 8).

As the vacuum reactor is internally divided into the plasma discharge space 15 and film deposition process space 16 that are separated from each other by means of the partitioning plate constructed as described above, the radicals that have been generated in the plasma discharge space 15 may only be delivered into the film deposition process space 16 through the through-holes 25, while the film deposition gas that has been delivered into the film deposition gas diffuse space 24 from outside the vacuum reactor may be delivered directly into the film deposition process space 16 through the film deposition gas diffuse holes 26, without making contact with the plasma or radicals.

In the RS-CVD apparatus disclosed in the patent application publication No. 2000-345349, the through-holes 25 on the electrically conductive partitioning plate 14 grounded to the earth are provided to meet the particular dimensional requirements so that the deposition gas cannot be diffused from the film deposition process space 16 back to the plasma discharge space 15, while at the same time the plasma generated in the plasma discharge space 15 cannot leak out into the film deposition process space 16.

In the RS-CVD apparatus disclosed in the patent application publication No. 2000-345349, the plasma generated in the plasma discharge space 15 will be prevented from making direct contact with the film deposition gas or substrate. Thus, the substrate placed in the film deposition process space 16 can be processed without being affected by the plasma and therefore without having any damage caused by the plasma.

### OBJECTS AND SUMMARY

The RS-CVD apparatus as proposed in the patent application publication No. 2000-345349 permits a substrate placed in the film deposition process space 16 to be processed without being affected by the plasma and therefore without having any damage caused by the plasma as described above, and is therefore estimated highly in the field of the manufacture of semiconductor devices in which such damages caused by the plasma are a serious problem.

It should be noted, however, that the RS-CVD apparatus as proposed in the patent application publication No. 2000-345349 remains yet to be improved in respect of meeting the requirements for processing many different kinds of substrates flexibly, such as the process of depositing a thin film on such substrates at high speeds.

In the RS-CVD apparatus, for example, Silane gas (SiH₄) is used as the film deposition gas, and nitrogen gas or hydrogen gas is delivered into the plasma discharge space in which nitrogen plasma or hydrogen plasma may be generated, thereby producing radicals. Those radicals may then be delivered into the substrate process space through the through-holes on the partitioning plate in which a Silicon nitride film or Silicon film may be deposited on the substrate being processed. In this case, it is difficult to produce the amount of radicals that is sufficient to provide a good film deposition by permitting it to react with the deposition gas within the substrate process space. The discharging that is caused by the atomic nitrogen or atomic hydrogen cannot generate the radicals efficiently. In addition, the atomic nitrogen or atomic hydrogen may become deactivated by hitting the inner walls of the through-holes as compared with the atomic oxygen. Thus, the radicals that are produced by the atomic nitrogen or atomic hydrogen are not satisfactory in respect of their amount or lifetime. After the thin film is deposited on the substrate, the surface of the thin film thus deposited may be finished without using the film deposition gas. In this case, it is prerequisite to deliver the sufficient amount of radicals into the substrate process space in order to reduce the processing time.

It is therefore one object of the present invention to provide a substrate processing apparatus wherein a substrate being processed and placed in the film deposition process space can be processed without being affected by the plasma and therefore without having any damages caused by the plasma, the requirements for processing many different kinds of substrates such as the thin film deposition process for such substrates can be met flexibly, and the substrate processing such as the thin film deposition process can be performed at high deposition rate.

It is another object of the present invention to provide a substrate processing method that is performed using the substrate processing apparatus defined above, whereby a substrate being processed and placed in the film deposition process space can be processed without being affected by the plasma and therefore without having any damages caused by the plasma, the requirements for processing many different kinds of substrates such as the thin film deposition process for such substrates can be met flexibly, and the substrate processing such as the thin film deposition process can be performed at high deposition rate.

In order to solve the problems associated with the prior art as described above, the present invention proposes to provide several aspects of the substrate processing apparatus and substrate processing method, respectively.

In a first aspect of the substrate processing apparatus, it includes a vacuum reactor that is internally divided into an upper part and a lower part that are separated from each other by means of an electrically conductive partitioning plate grounded to the earth, the upper part of the vacuum reactor located above the partitioning plate creating a plasma discharge space in which an rf electrode is disposed and the lower part of the vacuum reactor located below the partitioning plate creating a substrate process space in which a substrate support mechanism is disposed, wherein the partitioning plate has a plurality of through-holes provided vertically through the partitioning plate and an internal space isolated from the plasma discharge space and communicating with the substrate process space, with the plasma discharge space and substrate process space only communicating with each other through the plurality of through-holes on the partitioning plate, and wherein each of the plurality of through-holes on the partitioning plate is provided to meet the specific dimensional requirements, that is, it is provided to have the vertical length of between 5 mm and 30 mm, the bore diameter of between 5 mm and 30 mm and the aspect ratio of above 1 and below 2.

In a first aspect of the substrate processing method, it includes the steps of using the first aspect of the substrate processing apparatus, generating plasma and then producing radicals from such plasma in the plasma discharge space, delivering the radicals into the substrate process space through the through-holes on the partitioning plate, and processing the substrate held by the substrate support mechanism by utilizing the radicals.

In a second aspect of the substrate processing apparatus, it includes a vacuum reactor that is internally divided into an upper part and a lower part that are separated from each other by means of an electrically conductive partitioning plate grounded to the earth, the upper part of the vacuum reactor located above the partitioning plate creating a plasma discharge space in which an rf electrode is disposed and the lower part of the vacuum reactor located below the partitioning plate creating a substrate process space in which a substrate support mechanism is disposed, wherein the partitioning plate has a plurality of through-holes provided vertically through the partitioning plate and an internal space isolated from the plasma discharge space and communicating with the substrate process space, with the plasma discharge space and substrate process space only communicating with each other through the plurality of through-holes on the partitioning plate, and wherein the apparatus further includes an insulating plate disposed on the upper Side of and closely to the partitioning plate and having a plurality of through-holes provided vertically to pass through the partitioning plate, each of the plurality of through-holes on the partitioning plate and each corresponding one of the plurality of through-holes on the insulating plate being provided to face opposite each other and forming each vertical through-hole, wherein each of the vertical through-holes is provided to meet the specific dimensional requirements, that is, it is provided to have the vertical length of between 5 mm and 30 mm, the bore diameter of between 5 mm and 30 mm and the aspect ratio of above 1 and below 2.

In a second aspect of the substrate processing method, it includes the steps of using the second aspect of the substrate processing apparatus, generating plasma and then producing radicals from such plasma in the plasma discharge space, delivering the radicals into the substrate process space through the through-holes on the partitioning plate, and processing the substrate held by the substrate support mechanism by utilizing the radicals.

In any of the first and second aspects of the substrate processing method, the step of processing the substrate may include the step of depositing a thin film on the substrate held by the substrate support mechanism by causing the radicals and film deposition gas to react with each other in the substrate process space, and the step of finishing the surface of the thin film thus deposited on the substrate without using the film deposition gas.

The dimensional requirements that should be met by each of the through-holes on the partitioning plate in the first aspect of the substrate processing apparatus and the dimensional requirements that should be met by each of the vertical through-holes including each of the through-holes on the partitioning plate and each corresponding one of the through-holes on the insulating plate in the second aspect of the substrate processing apparatus in which the insulating plate is disposed on the upper Side of and closely to the partitioning plate (in either of the first or second aspect of the substrate processing apparatus, the dimensional requirements specify that each through-hole should have the vertical length of between 5 mm and 30 mm, the bore diameter of between 5 mm and 30 mm, and the aspect ratio of above 1 and below 2) have been adopted for the reasons that will be described below.

In any of the first and second aspects of the substrate processing apparatus, the vacuum reactor is internally divided into the upper and lower parts that are separated from each other by means of the electrically conductive partitioning plate grounded to the earth, the upper part of the vacuum reactor located above the partitioning plate creating the plasma discharge space in which the rf electrode is disposed and the lower part of the vacuum reactor located below the partitioning plate creating the substrate process space in which the substrate support mechanism is disposed. The partitioning plate has the plurality of through-holes provided vertically to pass through the partitioning plate and the internal space isolated from the plasma discharge space and communicating with the substrate process space. Specifically, in accordance with the first aspect of the substrate processing apparatus, the plasma discharge space and substrate process space may only communicate with each other through the plurality of through-holes on the partitioning plate, and in accordance with the second aspect of the substrate processing apparatus, the plasma discharge space and substrate process space may only communicate with each other through each of the vertical through-holes formed by each of the through-holes on the partitioning plate and each corresponding one of the through-holes on the insulating plate facing opposite each of the through-holes on the partitioning plate. A raw gas may only be delivered into the substrate process space through the internal space.

The radicals that have been generated in the plasma discharge space may thus be delivered into the substrate process space through the through-holes on the partitioning plate in the first aspect of the apparatus or through the vertical through-holes in the second aspect of the apparatus.

The vertical length, bore diameter and aspect ratio for each of the through-holes on the partitioning plate and each of the vertical through-holes should be defined by considering the lifetime of the radicals that may be generated in the plasma discharge space so that those radicals can last for as long as possible without being deactivated and can thus be used effectively.

The reason is that as the vertical length of each of the through-holes on the partitioning plate or each of the vertical through-holes is greater, the distance through which the radicals can travel becomes longer, and the radicals may have more chances of hitting the inner wall of each through-hole or vertical through-hole and thus becoming deactivated.

Specifically, if the bore diameter of each through-hole or vertical through-hole is less than 1 mm, the plasma will not enter the through-hole or the vertical through-hole. If the bore diameter is about 2 or 3 mm, it may cause the abnormal discharging in the through-holes or vertical through-holes. Any of the above cases is undesirable. Thus, it is desirable that the bore diameter of each through-hole or vertical through-hole should be 5 mm or greater Since this would produce the stable discharging instead of causing the abnormal discharging.

In the first or second aspect of the substrate processing apparatus described above, it is desirable that the substrate being processed should be kept away from the underside of the partitioning plate located to face opposite the substrate by about 30 mm so that the raw gas can only be delivered into the substrate process space through the internal space on the partitioning plate and then can be diffused uniformly onto the substrate.

In the first or second aspect of the substrate processing apparatus described above, it is desirable that the underside of the partitioning plate should be located closely to the substrate being processed in order to prevent the radicals from becoming deactivated, Since it is also located on the lower end Side of each of the through-holes on the partitioning plate or each of the vertical through-holes that is just located on the lower end of the plasma discharge space.

If the bore diameter of each of the through-holes on the partitioning plate or each of the vertical through-holes is greater than the distance between the substrate being processed and the underside of the partitioning plate located to face opposite the substrate, the plasma might be drawn into the contact surface between the substrate and the substrate support mechanism on which the substrate is placed, causing abnormal discharging.

As mentioned earlier, it is desirable that the distance between the substrate being processed and the lower Side of the partitioning plate facing opposite the substrate should be about 30 mm. For this reason, it is desirable that the bore diameter for each of the through-holes on the partitioning plate or each of the vertical through-holes should be at most 30 mm or not more than 30 mm.

If it is assumed that the radicals that have been generated in the plasma discharge space are traveling isotropically through the plasma discharge space, the amount of those radicals that can reach the substrate process space will depend on the amount of the radicals entering each of the through-holes that is determined by the bore diameter and the distance of each of the through-holes that will cause the radicals to have more chances of hitting the inner wall of the through-hole while traveling through the through-hole. Thus, the preferred range of the aspect ratio that is expressed by the ratio of the length to bore diameter of the through-hole is also important, and so should be defined by considering the lifetime of the radicals that may be generated in the plasma discharge space so that those radicals can last for as long as possible without being deactivated and can thus be used effectively.

The dimensional requirements that should be met by each of the through-holes on the partitioning plate or each of the vertical through-holes (either of which specifies that each through-hole or vertical through-hole should have the vertical length of between 5 mm and 30 mm, the bore diameter of between 5 mm and 30 mm, and the aspect ratio of above 1 and below 2), respectively, may be defined by considering the results of studying the above and by considering the lifetime of the radicals that may be generated in the plasma discharge space so that those radicals can last for as long as possible without being deactivated and can thus be used effectively.

In accordance with the first or second aspect of the substrate processing apparatus that has been described above, the processes that can occur against a substrate placed in the substrate process space may include the process of depositing a thin film on the substrate by using any of the film deposition gases, such as Silane gas, that can contribute to the film deposition, and the process of finishing the surface of the thin film thus deposited on the substrate in order to improve the film quality of the thin film by utilizing the radicals directly from the plasma discharge space without using the film deposition gas.

In accordance with the first or second aspect of the substrate processing apparatus that has been described above, the electrically conductive partitioning plate grounded to the earth and the insulating plate disposed above and closely to the partitioning plate may be fastened with the respective peripheral edges of the partitioning plate and insulating plate being tightened by means of fixing devices such as screws, for example.

The stability with which the discharging can be produced in the plasma discharge space and the amount of the plasma that can leak out into the substrate process space may thus be adjusted.

In accordance with the first or second aspect of the substrate processing apparatus that has been described above, the gases (plasma producing gases) that are delivered into the plasma discharge space in order to produce the plasma may include O₂, N₂, He, Ar, H₂, F₂, NF₃, SF₆ and Similar gases. Among these gases, NF₃ and SF₆ gases may be used during the cleaning stage to clean the inner walls of the substrate process space (for example, in order to remove any Silicon oxide film).

In accordance with the substrate processing apparatus and substrate processing method of the present invention, the requirements for processing many different kinds of substrates such as the thin film deposition process for such substrates can be met flexibly, and the substrate processing such as the thin film deposition process can be performed at high deposition rate and at low temperatures.

### BRIEF DESCRIPTION OF THE DRAWINGS

FIG. 1 is a cross sectional view illustrating one example of a first preferred embodiment of the vacuum processing apparatus according to the present invention;

FIG. 2 is a cross sectional view illustrating one example of a second preferred embodiment of the vacuum processing apparatus according to the present invention;

FIG. 3 is a cross sectional view illustrating another preferred example of the first embodiment shown in FIG. 1;

FIG. 4 is a cross sectional view illustrating another preferred example of the second embodiment shown in FIG. 2;

FIG. 5 is a cross sectional view illustrating the construction of a plurality of through-holes provided to pass vertically through the partitioning plate, although some non-essential parts are not shown for clarity of the illustration;

FIG. 6 is a schematic diagram illustrating one example of the embodiment in which the insulating plate is disposed on and closely to the upper Side of the partitioning plate, wherein it is assumed that each of the through-holes provided on the insulating plate has a bore diameter that is the same as that of each corresponding one of the through-holes provided on the partitioning plate, although some non-essential parts are not shown for clarity of the illustration;

FIG. 7 is a bottom view of the partitioning plate illustrating one example of how a substrate placed in the substrate process space is arranged in relation to the through-holes and film deposition gas diffusion holes provided on the partitioning plate; and

FIG. 8 is a cross sectional view illustrating one example of the partitioning plate employed in the conventional RS-CVD apparatus.

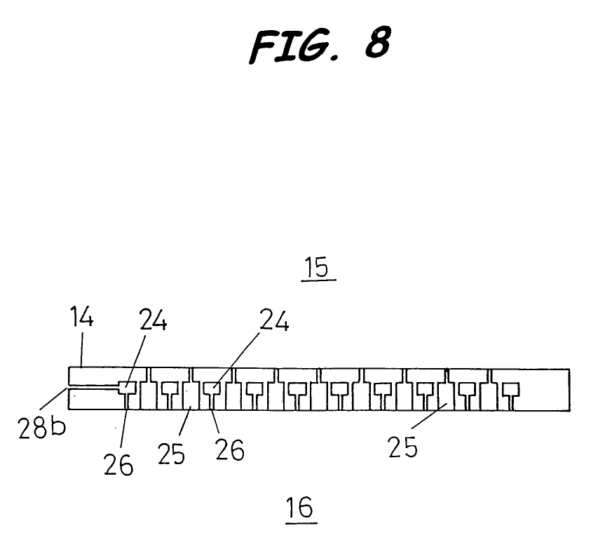

### BEST MODES OF EMBODYING THE INVENTION

By referring to the accompanying drawings, the following describes several preferred embodiments of the substrate processing apparatus according to the present invention in which as one of the processes that may be performed on the substrate placed in the substrate process space, a thin film may be deposited on the substrate.

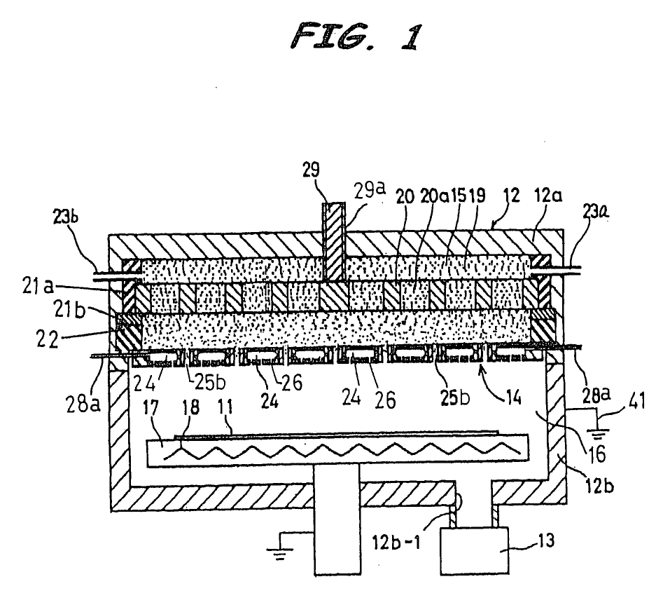

A first preferred embodiment of the substrate processing apparatus according to the present invention is now described by referring to FIG. 1.

The substrate processing apparatus includes a vacuum reactor 12 in the form of a vacuum container that is kept under a predetermined vacuum state by a pumping mechanism 13. For example, a thin film deposition may be performed on a substrate in the vacuum reactor 12. The pumping mechanism 13 is connected to a pumping port 12b-1 provided on the vacuum reactor 12.

The vacuum reactor 12 contains a partitioning plate 14 made of an electrically conductive material (such as SUS, aluminum and the like) that is placed in its horizontal position. The partitioning plate 14 has a round shape in plane, for example, and has its peripheral edge pressed against the lower Side of an annular electrically conductive fastening member 22 so that it can be kept hermetic.

The vacuum reactor 12 is internally divided into an upper part 12a and a lower part 12b, the upper part 12a creating a plasma discharge space 15 in which an rf electrode 20 is disposed and the lower part 12b creating a film deposition process space 16 in which a substrate support mechanism 17 is disposed. The partitioning plate 14 is located between the upper and lower parts 12a and 12b.

An upper annular isolating member 21a and a lower annular isolating member 21b are provided such that they may be interposed between the partitioning plate 14 and the upper part 12a when the rf electrode 20 is to be mounted as described later. Then, the partitioning plate 14 having its peripheral edge pressed against the lower Side of the peripheral edge of the electrically conductive fastening member 22 is provided so that the upper Side of the peripheral edge of the electrically conductive fastening member 22 can engage the lower annular isolating member 21b.

The partitioning plate 14 is grounded to the earth 41 by way of the electrically conductive fastening member 22.

The vacuum reactor 12 is thus internally divided into the upper and lower parts that are separated from each other by means of the electrically conductive partitioning plate 14, the upper part creating the plasma discharge space 15 and the lower part creating a film deposition process space 16 that is functionally equivalent to the substrate process space.

There are film deposition gas diffusion spaces 24 inside the partitioning plate 14. Each of the film deposition gas diffusion spaces 24 corresponds to an internal space, and is isolated from the plasma discharge space 15 as shown in FIG. 1. Each of the film deposition gas diffusion spaces 24 and film deposition process space 16 communicate with each other only through a plurality of film deposition gas diffusion holes 26.

The film deposition gas diffusion spaces 24 created inside the partitioning plate 14 are the spaces through which the film deposition gas delivered from outside the partitioning plate 14 can be diffused uniformly, and may then be supplied into the film deposition process space 16.

A film deposition gas delivery pipe 28a is connected to the film deposition gas diffusion spaces 24 on its lateral Side, and the film deposition gas may be delivered into the film deposition gas diffusion spaces 24 from any external supply source (not shown) through the film deposition gas delivery pipe 28a.

The film deposition gas that has been delivered into the film deposition gas diffusion spaces 24 inside the partitioning plate 14 through the film deposition gas delivery pipe 28a will be diffused in the film deposition gas diffusion spaces 24, going through the film deposition gas diffusion holes 26 into the film deposition process space 16 directly, that is, without making contact with the radicals or the plasma.

The partitioning plate 14 further has a plurality of through-holes 25b that are provided to pass vertically through the partitioning plate 14, and are distributed such that those through-holes 25b may be located on the areas of the partitioning plate 14 where the film deposition gas diffusion spaces 24 are not provided. The vacuum reactor 12 is divided into the plasma discharge space 15 and film deposition process space 16 that are separated from each other by means of the partitioning plate 14, and the plasma discharge space 15 and film deposition process space 16 communicate with each other only through the plurality of through-holes 25b on the partitioning plate 14.

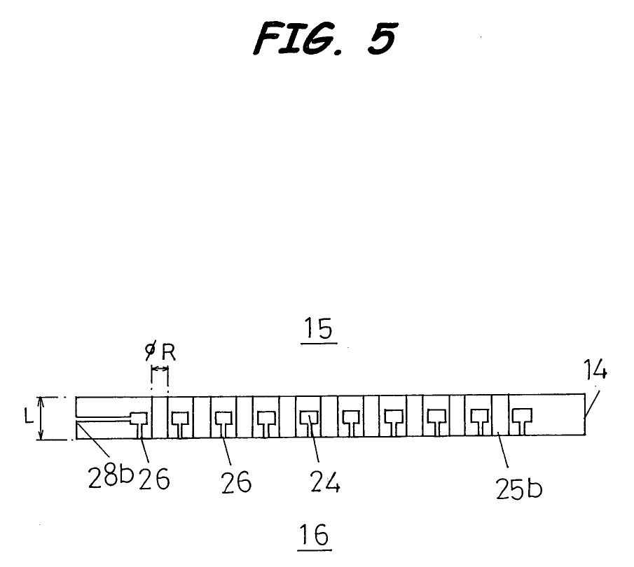

As shown in FIG. 5, each of the plurality of through-holes 25b on the partitioning plate 14 has the vertical length L of between 5 mm and 30 mm, the bore diameter R of between 5 mm and 30 mm, and the aspect ratio of above 1 and below 2.

A substrate 11 (for example, a glass substrate) being processed in the substrate processing apparatus is placed on the substrate support mechanism 17 disposed in the film deposition process space 16. The substrate 11 is placed such that it may be positioned substantially horizontal to the partitioning plate 14, with its upper Side (the Side being deposited) facing opposite the lower Side of the partitioning plate 14.

The substrate support mechanism 17 is grounded to the earth 41, and is maintained at the same ground potential as the vacuum reactor 12. In addition, there is a heater 18 inside the substrate support mechanism 17. This heater 18 maintains the substrate 11 being processed at a predetermined temperature.

FIG. 1 represents the first embodiment of the substrate processing apparatus according to the present invention.

In this substrate processing apparatus, a Silane gas is preferably used as the film deposition gas, and a glass substrate for the usual TFT is used so that a Silicon oxide film may be deposited as the gate insulating film on the upper surface of the glass substrate.

In the substrate processing apparatus shown in FIG. 1, plasma 19 may be generated in the plasma discharge space 15. The plasma discharge space 15 includes an insulating plate 32, the upper part 12a, and a plate-like rf electrode 20 arranged in the center between the insulating plate 32 and upper part 12a.

The plasma that is generated in the plasma discharge space 15 may go to the through-holes 25 on the partitioning plate 14 where the plasma may stay, and through which the plasma may then go into the substrate process space 16.

In the substrate processing apparatus shown in FIG. 1, the rf electrode 20 has a plurality of through-holes 20a that are provided to pass vertically through the rf electrode 20.

There is a power delivery rod 29 on the ceiling of the upper part 12a, and the power delivery rod 29 is connected to the rf electrode 20. The power delivery rod 29 may supply a discharging rf power to the rf electrode 20. The power delivery rod 29 is shielded by an insulating material 29a that insulates the power delivery rod 29 from other metal parts.

A plasma producing gas delivery pipe 23a is provided in the annular insulating member 21a, and is connected to an external plasma producing gas supply source for delivering any appropriate plasma producing gas, such as O₂, N₂, He, Ar, H₂, and F₂ gases, into the plasma discharge space 15.

Those plasma producing gas delivery pipes 23a are connected to the plasma producing gas supply source (not shown) and a cleaning gas supply source (not shown) through a mass flow controller (not shown) that controls the flow rate, respectively.

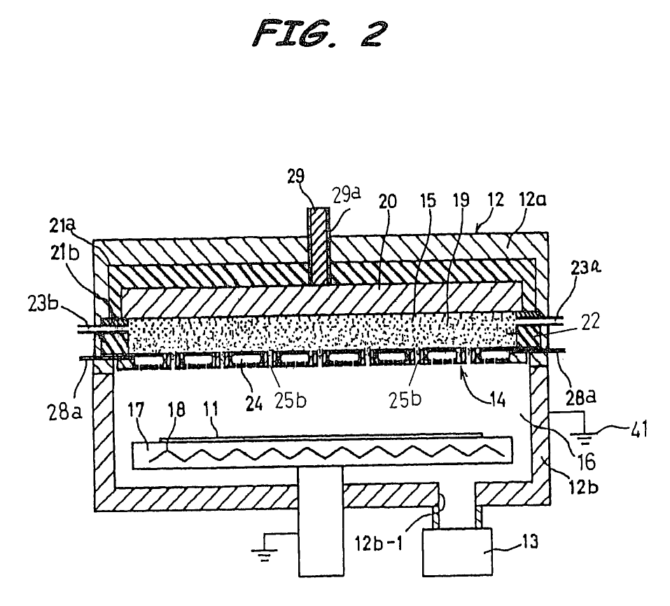

FIG. 2 represents the second embodiment of the substrate processing apparatus according to the present invention. The constructional features of the apparatus shown in FIG. 2 are that an insulating member 21a is provided inside the ceiling of the upper part 12a and an rf electrode 20 is arranged below the ceiling. The rf electrode 20 has no such through-holes 20a as those on the rf electrode in FIG. 1, and takes the Single plate form.

The plasma discharge space 15 is formed by a parallel flat-type electrode construction that includes the rf electrode 20 and insulating plate 32.

As is the case with the embodiment shown in FIG. 1, the plasma that is generated in the plasma discharge space 15 may go into the through-holes 25 on the partitioning plate 14 where the plasma may stay, and through which the plasma may then go into the substrate process space 16.

Other component parts of the construction in the embodiment of FIG. 2 that have not been described above are Similar to those of the construction in the embodiment of FIG. 1, and are given Similar reference numerals in FIG. 2. Therefore, details of those component parts are omitted here to avoid duplicate description.

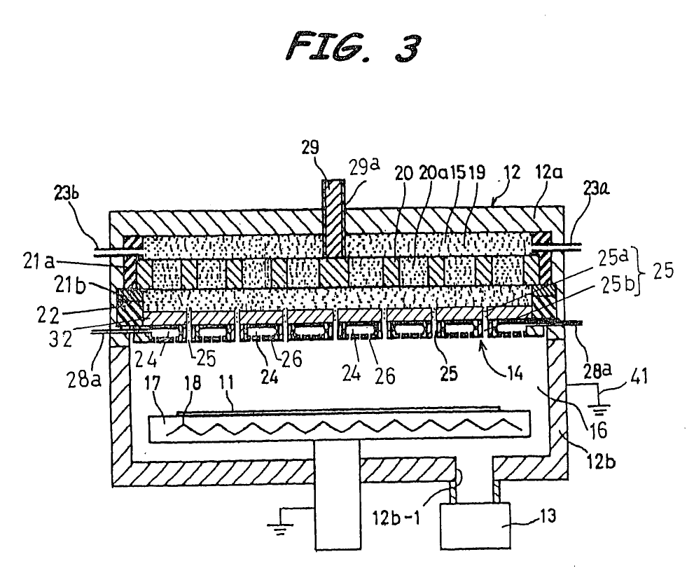

FIG. 3 is a cross sectional view of the substrate processing apparatus having the construction Similar to that in the embodiment of FIG. 1, in which the insulating plate 32 is disposed on and closely to the upper Side of the partitioning plate 14.

The isolating plate 32 that is disposed on and closely to the upper Side of the partitioning plate 14 (the Side on which the rf electrode is located) has a plurality of through-holes 25a that are provided to pass vertically through the isolating plate 32. Each of the plurality of through-holes 25b on the partitioning plate 14 is provided to face opposite each corresponding one of the plurality of through-holes 25b on the insulating plate 32 as viewed in the vertical direction. Each of a plurality of vertical through-holes 25 may then be formed by each of the through-holes 25b on the partitioning plate 14 and each corresponding one of the through-holes 25a facing opposite each of the through-holes 25b.

When the isolating plate 32 is to be placed on the upper Side of the partitioning plate 14, the isolating plate 32 may be mounted closely to the partitioning plate 14 with their respective peripheral edges being tightened by means of screws, for example, although this is not shown.

The insulating plate 32 may be made of alumina or quartz.

Each of the plurality of vertical through-holes 25 has the vertical length of between 5 mm and 30 mm, the bore diameter of between 5 mm and 30 mm, and the aspect ratio of above 1 and below 2.

The embodiment of FIG. 3 only differs from the embodiment of FIG. 1 in that the insulating plate 32 is disposed on the upper Side of the partitioning plate 14. Other component parts of the construction in the embodiment of FIG. 3 that have not been described above are Similar to those of the construction in the embodiment of FIG. 1, and are given Similar reference numerals in FIG. 3. Therefore, details of those component parts are omitted here to avoid the duplicate description.

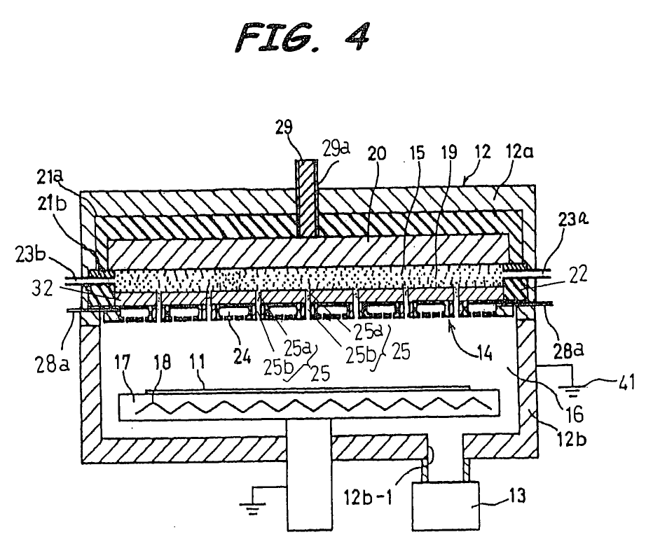

FIG. 4 is a cross sectional view of the substrate processing apparatus having the construction Similar to that in the embodiment of FIG. 2, in which the insulating plate 32 is disposed on and closely to the upper Side of the partitioning plate 14 as is the case with the embodiment of FIG. 3.

The embodiment of FIG. 4 only differs from the embodiment of FIG. 2 in that the insulating plate 32 is disposed on the upper Side of the partitioning plate 14. Other component parts of the construction in the embodiment of FIG. 4 that have not been described above are Similar to those of the construction in the embodiments of FIGS. 2 and 3, and are given Similar reference numerals in FIG. 4. Therefore, details of those component parts are omitted here to avoid the duplicate description.

The insulating plate 32 may be made of any number of sheets so that any desired thickness can be obtained. In this case, each of the vertical through-holes 25 including each through-hole 25a and each through-hole 25b should have the vertical length of between 5 mm and 30 mm, the bore diameter of between 5 mm and 30 mm, and the aspect ratio of above 1 and below 2.

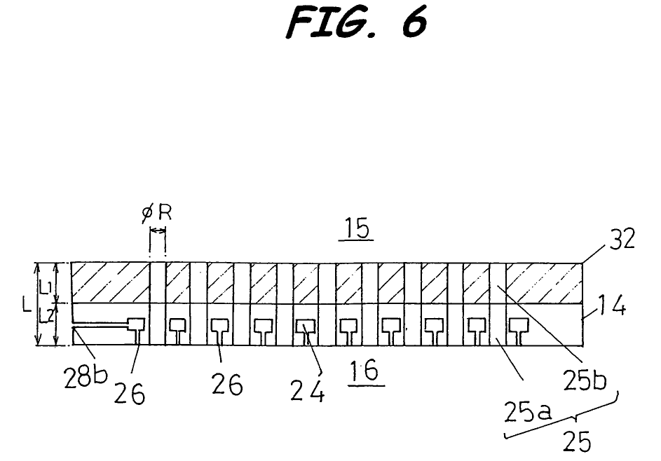

FIG. 6 shows one example of the embodiment in which the insulating plate 32 is disposed on and closely to the upper Side of the electrically conductive partitioning plate 14, wherein each of the through-holes 25b on the insulating plate 32 has the bore diameter that is the same as that for each corresponding one of the through-holes 25a on the partitioning plate 14. The partitioning plate 14 made of an electrically conductive material and grounded to the earth has the same shape and total thickness as those of the insulating plate 32, and the insulating plate 32 may be disposed on the upper Side of the partitioning plate 14 (on the Side on which the plasma discharge space 15 is located) and closely to the partitioning plate 14. Each of the plurality of vertical through-holes 25 may then be formed by linking each of the plurality of through-holes 25b on the insulating plate 32 with each of the plurality of through-holes 25a on the partitioning plate 14 that faces opposite each corresponding one of the through-holes 25b on the insulating plate 32.

The aspect ratio of each of the vertical through-holes 25 may be changed by modifying the thickness of the insulating plate 32, and the density of plasma that is delivered into the substrate process space 16 may be adjusted accordingly.

In any of the embodiments described so far, in which the substrate processing such as the thin film deposition process is performed, the film deposition gas such as Silane gas and the radicals generated in the plasma discharge space 15 may be delivered into the substrate process space 16 through the respective film deposition gas diffusion holes 26, through-holes 25b on the partitioning plate 14 and vertical through-holes 25. Thus, both the film deposition gas and radicals should preferably be diffused uniformly onto the entire surface of the substrate 11 placed in the substrate process space 16.

This is desirable because the thickness of the thin film being deposited on the surface of the substrate as well as the film quality of the thin film thus deposited in the direction of thickness can be made uniform over the total area of the surface of the substrate.

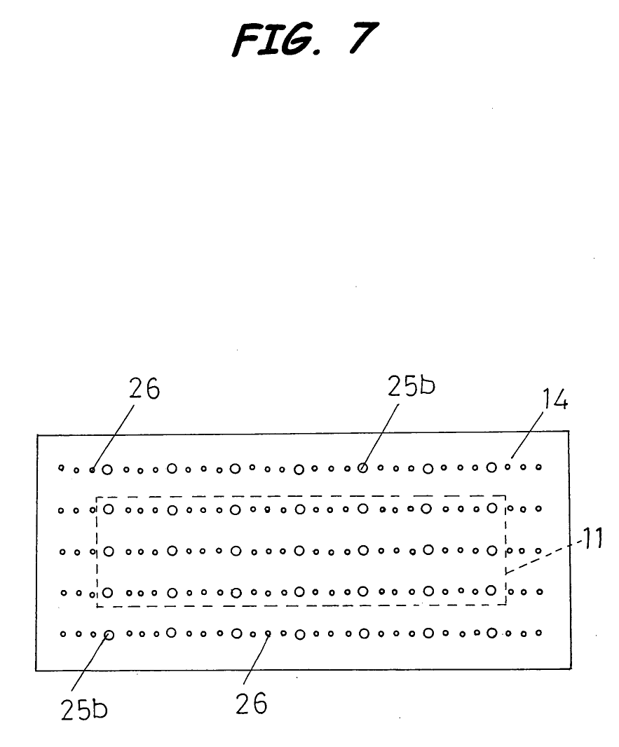

FIG. 7 shows a preferred example in which a plurality of film deposition gas diffusion holes 26 may be provided at equal intervals with regard to the entire surface of a substrate 11 being processed, and a plurality of through-holes 25b on the partitioning plate 14 may also be provided at equal intervals with regard to the entire surface of the substrate 11 being processed. Then, the film deposition gas and plasma may be diffused uniformly against the substrate 11 being processed. In this regard, the Size of the partitioning plate 14 should preferably be the same as or greater than the Size of the substrate 11 being processed.

### EMBODIMENT 1

The following describes one example of the substrate processing method in which a thin film deposition (silicon oxide film deposition) for a substrate is performed using the substrate processing apparatus according to any of the embodiments of the invention that have been described so far.

The substrate processing apparatus described in accordance with the embodiment shown in FIG. 1 is used, in which as shown in FIG. 5, the partitioning plate 14 has a plurality of through-holes 25b, each of which has the vertical length L of 20 mm, the bore diameter R of 15 mm and the aspect ratio of 1.33.

A substrate 11 being processed (glass substrate) may be transferred by a transfer robot (not shown) into the vacuum reactor 12, where it may then be placed on the substrate support mechanism 17. Then, the vacuum reactor 12 may be maintained in a predetermined vacuum state by causing the pumping mechanism 13 to pump the air out of the reactor, reducing the internal pressure.

Next, oxygen gas may be delivered into the plasma discharge space 15 in the vacuum reactor 12 through the plasma producing gas delivery pipe 23a.

In the meantime, any appropriate film deposition gas such as Silane gas may be delivered into the film deposition gas diffusing spaces 24 on the partitioning plate 14 through the film deposition gas delivery pipe 28a. Then, the Silane gas may be diffused in the film deposition gas diffusion holes 24, going through the film deposition gas diffusion holes 26 into the film deposition process space 16 directly, that is, without making contact with the radicals or the plasma.

The substrate support mechanism 17 disposed in the film deposition process space 16 is previously maintained at a predetermined temperature by energizing the heater 18.

Under the conditions specified above, an rf power may be supplied to the electrode 20 through the power delivery rod 29. This rf power will cause a discharge that may produce oxygen plasma 19. The oxygen plasma 19 thus produced may then cause oxygen radicals (neutral excited active species) to be generated. The oxygen radicals thus generated may then be delivered into the film deposition process space 16 through the through-holes 25b on the partitioning plate 14 as indicated by an arrow 30.

A chemical reaction may then be caused between the Silane gas that has been delivered into the film deposition process space 16 through the film deposition diffusion holes 26 directly, that is, without making contact with the radicals or plasma and the oxygen radicals that have been delivered into the film deposition process space 16 through the through-holes 25b on the partitioning plate 14. A thin film such as Silicon oxide film may thus be deposited on the surface of the substrate 11 (glass substrate) being processed.

The oxygen plasma 19 that has thus been generated in the plasma discharge space 15 is going through the through-holes 25b on the partitioning plate 14 where the oxygen plasma 19 will stay because the holes 25b has the particular dimensional requirements described above, and may then go into the film deposition process space 16 where the film deposition process may proceed.

As the substrate 11 (glass substrate) being processed is not exposed directly to the oxygen plasma 19, the film deposition process can proceed without being affected by the oxygen plasma 19 and therefore without having any damages caused by the oxygen plasma 19.

The following list provides the conditions under which the Silicon oxide film may be deposited by performing the film deposition process described so far by using the substrate processing apparatus according to any of the embodiments of the present invention that have been described so far:

| Substrate | Silicon substrate |
|---|---|
| Rf power | 150 (W) |
| Plasma discharge gas O₂ | 500(sccm) (5.0 × 10⁻¹ (1/min) |
| Plasma discharge gas N₂ | 20(sccm) (2.0 × 10⁻² (1/min) |
| Raw gas (film deposition gas) SiH₄ | 4(sccm) (4.0 × 10⁻³ (1/min) |
| Carrier gas Ar | 70(sccm) (7.0 × 10⁻² (1/min) |
| Pressure in plasma discharge | 40(Pa) |
| space | |
| Pressure in film deposition | 40(Pa) |
| process space | |
| Substrate temperature | 300 (° C.) |
| Film deposition rate for | 25 (nm/min) |
| SiO₂ film | |

The following list provides the conditions under which the Silicon nitride film may be deposited by performing the film deposition process described so far by using the substrate processing apparatus according to any of the embodiments of the present invention that have been described so far:

| Substrate | Silicon substrate |
|---|---|
| Rf power | 150 (W) |
| Plasma discharge gas Hₑ | 500(sccm) (5.0 × 10⁻¹ (1/min) |
| Plasma discharge gas N₂ | 50(sccm) (5.0 × 10⁻² (1/min) |
| Raw gas (film deposition gas) SiH₄ | 5(sccm) (5.0 × 10⁻³ (1/min) |
| Carrier gas Hₑ | 70(sccm) (7.0 × 10⁻² (1/min) |
| Pressure in plasma discharge | 40(Pa) |
| space | |
| Pressure in film deposition | 40(Pa) |
| process space | |
| Substrate temperature | 300 (° C.) |
| Film deposition rate for | 5 (nm/min) |
| SiN film | |

The following list provides the conditions under which the amorphous Silicon film (a-Si film) may be deposited by performing the film deposition process described so far by using the substrate processing apparatus according to any of the embodiments of the present invention that have been described so far:

| Substrate | Silicon substrate |
|---|---|
| Rf power | 150 (W) |
| Plasma discharge gas Aᵣ | 500(sccm) (5.0 × 10⁻¹ (1/min) |
| Raw gas (film deposition gas) SiH₄ | 5(sccm) (5.0 × 10⁻³ (1/min) |
| Carrier gas Ar | 70(sccm) (7.0 × 10⁻² (1/min) |
| Pressure in plasma discharge | 40(Pa) |
| space | |
| Pressure in film deposition | 40(Pa) |
| process space | |
| Substrate temperature | 300 (° C.) |
| Film deposition rate for | 10 (nm/min) |
| a-Si film | |

### EMBODIMENT 2

In the embodiment of the substrate processing method that will be described below, the substrate processing apparatus in the embodiment shown in FIG. 1 is used, wherein the apparatus includes the partitioning plate 14 having a plurality of through-holes 25b each of which has the vertical length L of 20 mm, the bore diameter R of 15 mm and the aspect ratio of 1.33 as shown in FIG. 5. In this embodiment, a metal oxide film may be deposited using, as the film deposition gas, an organic raw gas that contains any of the metal elements such as ruthenium, hafnium, titanium, tantalum, zirconium, aluminum and the like.

A substrate 11 being processed (silicon substrate) may be transferred by a transfer robot (not shown) into the vacuum reactor 12, and may then be placed on the substrate support mechanism 17. Then, the vacuum reactor 12 may be maintained in a predetermined vacuum state by causing the pumping mechanism 13 to pump the air out of the reactor, reducing the internal pressure.

Next, the oxygen gas may be delivered into the plasma discharge space 15 in the vacuum reactor 12 through the plasma producing gas delivery pipe 23a.

In the meantime, an organic raw gas containing a metal element such as hafnium-t-butoxide (having the molecular formula of Hf[OC(CH₃)₃]₄)) may be delivered into the film deposition gas diffusion spaces 24 on the partitioning plate 14 through the film deposition gas delivery pipe 28a. The hafnium-t-butoxide is in a liquid state at room temperature, and may then be vaporized by a vaporizer (not shown) (this organic raw gas in its vaporized state will be referred to hereinafter as “the organic raw gas”). Then, the organic raw gas may be delivered through the film deposition gas diffusion holes 24 on the partitioning plate 14 by connecting an organic raw gas conduit (not shown) that is kept at the temperature above the condensation point to the film deposition gas pipe 28a in order to prevent the organic raw gas in its vaporized state from being condensed. The partitioning plate 14 as well as the organic raw gas conduit (not shown) should be kept at the temperature above the condensation point. Thus, the organic raw gas (hafnium-t-butoxide) may be delivered through the film deposition gas diffusion spaces 24 together with the carrier gas (for example, argon gas), through which the organic raw gas as well as the carrier gas may be diffused, and may then be delivered through the film deposition gas diffusion holes 26 into the film deposition process space 16 directly, that is, without making contact with the radicals or plasma.

The substrate support mechanism 17 disposed in the film deposition process space 16 is previously maintained at a predetermined temperature by energizing the heater 18.

Under the conditions specified above, an rf power may be supplied to the electrode 20 through the power delivery rod 29. This rf power will cause a discharge that may produce oxygen plasma 19 within the plasma discharge space 15. The oxygen plasma 19 thus produced may then cause oxygen radicals (neutral excited active species) to be generated. The oxygen radicals thus generated may then be delivered into the film deposition process space 16 through the through-holes 25b on the partitioning plate 14 as indicated by an arrow 30.

A chemical reaction may then be caused between the organic raw gas (hafnium-t-butoxide) that has been delivered into the film deposition process space 16 through the film deposition diffusion holes 26 directly, that is, without making contact with the radicals or plasma and the oxygen radicals that have been delivered into the film deposition process space 16 through the through-holes 25b on the partitioning plate 14. A thin film such as hafnium oxide (HfO₂) may thus be deposited on the surface of the substrate 11 (glass substrate) being processed.

The oxygen plasma 19 that has thus been generated in the plasma discharge space 15 is going through the partitioning plate through-holes 25b where the oxygen plasma 19 will stay because the holes 25b has the particular dimensional requirements described above, and may then go into the film deposition process space 16 where the film deposition process may proceed.

As the substrate 11 (glass substrate) being processed is not exposed directly to the oxygen plasma 19, the film deposition process can proceed without being affected by the oxygen plasma 19 and therefore without having any damages caused by the oxygen plasma 19.

The organic raw gas (hafnium-t-butoxide) that has been delivered into the film deposition process space 16 through the film deposition diffusion holes 26 directly, that is, without making contact with the radicals or plasma may react chemically with the carrier gas (for example, argon gas) and with the oxygen radicals that have been delivered into the film deposition process space 16 through the through-holes 25b on the partitioning plate 14. A thin film such as hafnium oxide (HfO₂) may thus be deposited on the surface of the substrate 11 (silicon substrate) being processed.

The following list provides the conditions under which the hafnium oxide (HfO₂) film may be deposited on the substrate:

| Substrate | Silicon substrate |
|---|---|
| Rf power | 150 (W) |
| Plasma discharge gas O₂ | 500(sccm) (5.0 × 10⁻¹ (1/min) |
| Carrier gas Ar | 50(sccm) (5.0 × 10⁻² (1/min) |
| Pressure in plasma discharge | 50(Pa) |
| space | |
| Pressure in film deposition | 50(Pa) |
| process space | |
| Substrate temperature | 370 (° C.) |
| Partitioning plate temperature | 90 (° C.) |
| Organic raw gas temperature | 45 to 60 (° C.) |

Though the present invention has been described with reference to the particular preferred embodiments of the present invention by referring to the accompanying drawings, it should be understood that the present invention is not restricted to those embodiments, and various changes and modifications may be made without departing from the spirit and scope of the invention as defined in the appended claims.

What is claimed is:

1. A substrate processing method including the steps of:
using a substrate processing apparatus including:
a vacuum reactor; and
an electrically conductive partitioning plate grounded to the earth, wherein the vacuum reactor is internally divided into an upper part and a lower part that are separated from each other by means of the partitioning plate, the upper part of the vacuum reactor located above the partitioning plate being a plasma discharge space in which an rf electrode is arranged and the lower part of the vacuum reactor located below the partitioning plate being a substrate process space in which a substrate support mechanism is disposed, and the partitioning plate has a plurality of through-holes that are provided to pass vertically through the partitioning plate, and the partitioning plate has an internal space that is isolated from the plasma discharge space and communicates with the substrate process space, the plasma discharge space and substrate process space only communicating with each other through the plurality of through-holes provided in the partitioning plate and a raw material gas being only delivered into the substrate process space through the internal space in the partitioning plate, wherein
each of the plurality of through-holes in the partitioning plate is provided to have a vertical length of between 5 mm and 30 mm, a bore diameter of between 5 mm and 30 mm and an aspect ratio of above 1 and below 2;
generating plasma in the plasma discharge space and then producing radicals from such plasma;
delivering the plasma into the substrate process space through the plurality of through-holes on the partitioning plate; and
performing the process on a substrate being held by the substrate support mechanism.

2. A substrate processing method including the steps of:
using a substrate processing apparatus including:
a vacuum reactor; and
an electrically conductive partitioning plate grounded to the earth, wherein the vacuum reactor is internally divided into an upper part and a lower part that are separated from each other by means of the partitioning plate, the upper part of the vacuum reactor located above the partitioning plate being a plasma discharge space in which an rf electrode is arranged and the lower part of the vacuum reactor located below the partitioning plate being a substrate process space in which a substrate support mechanism is disposed, and the partitioning plate has a plurality of through-holes that are provided to pass vertically through the partitioning plate, and has an internal space that is provided to be isolated from the plasma discharge space and communicate with the substrate process space, the plasma discharge space and substrate process space only communicating with each other through the plurality of through-holes provided on the partitioning plate and a raw gas being only delivered into the substrate process space through the internal space in the partitioning plate, wherein the substrate processing apparatus further includes:
an insulating plate disposed on and closely to the upper side of the partitioning plate and having a plurality of through-holes provided to pass vertically through the insulating plate, each of the plurality of through-holes on the insulating plate being provided to face opposite each corresponding one of the plurality of through-holes on the partitioning plate as viewed in the vertical direction, and each of the plurality of through-holes on the partitioning plate and each of the plurality of through-holes on the insulating plate being provided to have a vertical length of between 5 mm and 30 mm, a bore diameter of between 5 mm and 30 mm and an aspect ratio of above 1 and below 2;
generating plasma in the plasma discharge space and then producing radicals from such plasma;
delivering the plasma into the substrate process space through the plurality of through-holes on the partitioning plate; and
performing the process on a substrate being held by the substrate support mechanism.
